(19) United States
(12) Patent Application Publication
(10) Pub. No.: US 2024/0150652 A1
(43) Pub. Date: May 9, 2024

(54) QUANTUM DOT STRUCTURE, FORMING METHOD THEREOF AND LIGHT-EMITTING DEVICE INCLUDING THE SAME

(71) Applicant: Lextar Electronics Corporation, Hsinchu City (TW)

(72) Inventors: Pei Cong YAN, Hsinchu City (TW); Chia-Chun HSIEH, Hsinchu City (TW); Huei Ping WANG, Hsinchu City (TW); Hung-Chun TONG, Hsinchu City (TW); Yu-Chun LEE, Hsinchu City (TW)

(21) Appl. No.: 18/498,271

(22) Filed: Oct. 31, 2023

(30) Foreign Application Priority Data
Nov. 7, 2022 (TW) 111142348

(51) Int. Cl. C09K 11/88; C09K 11/02; H01L 33/50

(52) U.S. Cl. CPC C09K 11/883; C09K 11/025; H01L 33/502; B82Y 20/00

(57) ABSTRACT

The disclosure relates to a quantum dot structure. The quantum dot structure includes a quantum dot and a cloud-like shell covering a portion of the quantum dot and having an irregular outer surface. The quantum dot includes: a core; a first shell discontinuously around a core surface of the core; and a second shell between the core and the first shell and encapsulating the core surface of the core, wherein the second shell has an irregular outer surface.

### CROSS REFERENCE TO RELATED APPLICATIONS

This application claims priority of Taiwan Patent Application No. 111142348, filed on Nov. 7, 2022, and the entirety of which is incorporated by reference herein.

### Technical Field

The disclosure relates to a quantum dot structure, a forming method thereof and a light-emitting device including the same, and, in particular, it relates to a quantum dot structure with excellent moisture and oxygen resistance properties, a forming method thereof and a light-emitting device including the same.

### BACKGROUND

### Description of the Related Art

Quantum dots (QDs) are nanoscale semiconductor materials. Quantum dots usually have spherical or sphere-like crystal structures formed by several hundred to several thousand atoms. Quantum dots are wavelength conversion materials that have the advantage of high color saturation and are therefore highly advantageous for Wide Color Gamut (WCD) display technology.

However, quantum dots are susceptible to oxidation in the presence of water and oxygen. Oxidation of quantum dots may cause problems such as the shifting of their luminous wavelengths, a widening of the full width at half maximum of their luminous spectrum, and lower quantum efficiency. Therefore, there is still a need to find quantum dots that have better resistance or tolerance to oxygen and moisture.

### SUMMARY

In view of the above needs, the disclosure provides a quantum dot structure with better resistance or tolerance to oxygen or moisture.

An embodiment of the disclosure provides a quantum dot structure, comprising a quantum dot, and a cloud-like shell covering a portion of the quantum dot and having an irregular outer surface. The quantum dot comprises a core; a first shell discontinuously around a core surface of the core; and a second shell between the core and the first shell and encapsulating the core surface, wherein the second shell has an irregular outer surface.

An embodiment of the disclosure provides a method of forming quantum dot structures, comprising: providing a quantum dot core solution comprising a plurality of cores; providing a shell precursor solution to the quantum dot core solution to form a quantum dot precursor solution; heating the quantum dot precursor solution at a first temperature to form a quantum dot solution; and continuously stirring the quantum dot solution at a second temperature to form quantum dot structures. The quantum dot solution comprises quantum dots, wherein each of the quantum dots comprises a first shell and a second shell above a core surface of a core, wherein the first shell is discontinuously formed around the core surface, the second shell is formed between the core and the first shell and encapsulating the core surface, and the second shell has an irregular outer surface. Each of the quantum dot structures has a cloud-like shell covering a portion of the quantum dot. The second temperature is greater than or equal to the first temperature.

In addition, an embodiment of the disclosure provides a light-emitting device, comprising: a light source emitting a first light; and a wavelength conversion component absorbing part of the first light and converting the part of the first light into a second light, wherein the wavelength conversion component comprises a quantum dot stricture mentioned above.

According to the embodiments of the disclosure, the quantum dot structure of the disclosure comprises a quantum dot and a cloud-like shell covering a portion of the quantum dot and having an irregular outer surface. The quantum dot structure of the disclosure may have better resistance or tolerance to the environmental damage factors, such as water, oxygen or free radicals base on the structure thereof, and the reliability or luminous life of the quantum dot structure could be further enhanced thereby. The method of forming quantum dot structures disclosed in the disclosure can form quantum dot structures having better reliability or longer luminescence lifetime, and a light-emitting device comprising the quantum dot structures can also have better reliability or longer luminescence life.

### BRIEF DESCRIPTION OF THE DRAWINGS

Aspects of the disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a flowchart of a method of forming quantum dot structures according to some embodiments of the disclosure.

FIG. 2 illustrates a schematic view of a quantum dot according to some embodiments of the disclosure.

FIG. 3 illustrates a schematic view of a quantum dot according to some embodiments of the disclosure.

FIG. 4 illustrates a schematic view of a quantum dot structure according to some embodiments of the disclosure.

FIG. 5 illustrates a schematic view of a quantum dot structure according to some embodiments of the disclosure.

FIG. 6A illustrates a schematic view of a light-emitting device according to some embodiments of the disclosure.

FIG. 6B illustrates a schematic view of a light-emitting device according to some embodiments of the disclosure.

FIG. 6C illustrates a schematic view of a wavelength conversion portion according to some embodiments of the disclosure.

FIG. 7 is a transmission electron microscope (TEM) image of comparative quantum dots according to some embodiments of the disclosure.

FIG. 8 is a TEM image of comparative quantum dots according to some embodiments of the disclosure.

FIG. 9 is a TEM image of quantum dot structures according to some embodiments of the disclosure.

FIG. 10 is a folding line diagram which shows the luminescence intensities of the light-emitting devices of Example and Comparative Example of the disclosure in a nitrogen environment as a function of time.

FIG. 11 is a folding line diagram which shows the luminescence intensities of the light-emitting devices of Example and Comparative Example of the disclosure in a general environment as a function of time.

### DETAILED DESCRIPTION

The following disclosure provides many different embodiments, or examples, for implementing different features of the provided subject matter. Specific examples of components and arrangements are described below to simplify the disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

It should be understood that additional operations can be provided before, during, and/or after the stages described in these embodiments. Some of the stages that are described can be replaced or eliminated for different embodiments.

Furthermore, spatially relative terms, such as “beneath,” “below,” “lower,” “above,” “upper”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Here, the terms “about”, “approximately”, “substantially” usually means within 20%, within 10%, within 5%, within 3%, within 2%, within 1% or within 0.5% of a given value or range. Here, the given value is an approximate number. That is, in the absence of a specific description of “about”, “approximately”, “substantially”, the meaning of “about”, “approximately”, “substantially” may still be implied. Besides, the expression “a-b” indicates the range includes values greater than or equal to a and values less than or equal to b.

Unless otherwise defined, all terms (including technical and scientific terms) used herein have the same meaning as commonly understood by a person skilled in the art to which the invention pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein.

Different embodiments disclosed below may reuse the same reference symbols and/or labels. These repetitions are for the purpose of simplicity and clarity and are not intended to limit the specific relationship between the various embodiments and/or structures discussed below.

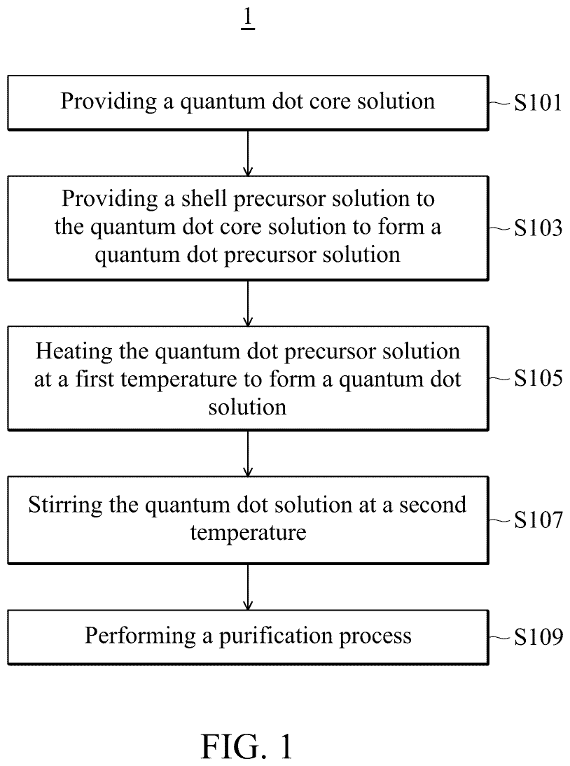

Some embodiments of the disclosure provide a method of forming quantum dot structures. The forming method of the quantum dot structures comprises: providing a quantum dot core solution comprising a plurality of cores; providing a shell precursor solution to the quantum dot core solution to form a quantum dot precursor solution; heating the quantum dot precursor solution at a first temperature to form a quantum dot solution comprising a plurality of quantum dots, wherein each of the quantum dots comprises a first shell discontinuously around a core surface of the core above the core surface and a second shell formed between the core and the first shell, encapsulating the core surface, and having an irregular outer surface; and continuously stirring the quantum dot solution at a second temperature to form quantum dot structures. Each of the quantum dot structures comprises a quantum dot and a cloud-like shell covering a portion of the quantum dot. The second temperature is greater than or equal to the first temperature. FIG. 1 illustrates a flowchart of a forming method 1 of quantum dot structures according to some embodiments of the disclosure. As shown in FIG. 1, the forming method 1 of quantum dot structures comprises: a step S101 of providing a quantum dot core solution, a step S103 of providing a shell precursor solution to the quantum dot core solution to form a quantum dot precursor solution, a step S105 of heating the quantum dot precursor solution at a first temperature to form a quantum dot solution, and a step S107 of stirring the quantum dot solution at a second temperature.

The quantum dot core solution provided in the step S101 comprises a plurality of cores. In some embodiments, the step S101 of providing a quantum dot core solution comprises a step of mixing a first core precursor solution and a second core precursor solution to form a core precursor mixture solution and a step of heating the core precursor mixture solution to form cores. In some embodiments, the first core precursor solution and the second core precursor solution may comprise any material which can form a core comprising an inorganic conductor material or an inorganic semiconductor material after the mixing and heating steps. In some embodiments, the first core precursor solution and/or the second core precursor solution may comprise inorganic semiconductor materials of Group II, Group III, Group IV, Group V, Group VI, or a combination thereof. The heating temperature may be 170° C.-270° C.

In the step S103, the shell precursor solution is provided to the quantum dot core solution obtained from the step S101 to mix the shell precursor solution and the quantum dot core solution to form the quantum dot precursor solution. In some embodiments, the shell precursor solution may comprise materials that can form shells in subsequent stages. The shells may comprise a shell (i.e. a first shell and second shell hereinafter) encapsulating the core in the quantum dot core solution and a cloud-like shell covering a portion of the quantum dot comprising the first shell, the second shell and the core. The shells have the same materials as the core in the quantum dot core solution, or have materials with a relatively matched lattice. In some embodiments, the shell precursor solution may comprise inorganic semiconductor materials of Group II, Group III, Group IV, Group V, Group VI, or a combination thereof. The equivalent ratio of the quantum dot core solution to the shell precursor solution may be about 1:100-1:1. In some embodiments, the step S103 of providing the shell precursor solution to the quantum dot core solution to form the quantum dot precursor solution comprises slowly introducing the shell precursor solution into the quantum dot core solution obtained from the step S101 within an introduction time of about 1 to 2 hours. The introduction rate of the shell precursor solution is about 0.016-1.6 eq/min when the core content in the quantum dot core solution is counted as 1 equivalent. In some embodiments, the introduction rate of the shell precursor solution may be about 0.05-1.6 eq/min, about 0.06-1.6 eq/min, about 0.05-1.55 eq/min, about 0.06-1.55 eq/min, about 0.05-1.5 eq/min, or about 0.06-1.5 eq/min. When the introduction rate of the shell precursor solution is about 0.016-1.6 eq/min, an appropriate reaction time between molecules in the shell precursor solution and the quantum dot core solution can be achieved. Therefore, these molecules can form irregular shells while maintaining the luminescent properties of the quantum dots formed in the subsequent stages by attractive and repulsive forces therebetween. When the introduction rate of the shell precursor solution is less than 0.016 eq/min, the reaction time between the molecules in the shell precursor solution and the quantum dot core solution may be too long. Therefore, these molecules tend to form bulks and the quantum dots formed in the subsequent stages may lose luminescence properties. When the introduction rate of the shell precursor solution is greater than about 1.6 eq/min, the forces between the molecules in the shell precursor solution and the quantum dot core solution and a growth rate of the shells are not balanced. Therefore, the shells formed in the subsequent stages have large shell gaps and are not able to cluster around the core, thereby failing to form quantum dot structures that have better resistance or tolerance to environmental damage factors.

In some embodiments, the shell precursor solution may comprise a first shell precursor solution and a second shell precursor solution. In some embodiments, the equivalent ratio of the first shell precursor solution to the second shell precursor solution may be about 1:1. In some embodiments, the step S103 may comprise introducing the first shell precursor solution at a first introduction rate and introducing the second shell precursor solution at a second introduction rate. The first introduction rate is about 0.016-1.6 eq/min and the second introduction rate is about 0.016-1.6 eq/min when the core content in the quantum dot core solution is counted as 1 equivalent. The first introduction rate is greater than or equal to the second introduction rate. In some embodiments, the first introduction rate may be about 0.1-1.6 eq/min, about 0.15-1.6 eq/min, about 0.2-1.6 eq/min, about 0.3-1.6 eq/min, about 0.15-1.55 eq/min, about 0.2-1.55 eq/min, about 0.3-1.55 eq/min, about 0.15-1.5 eq/min, about 0.2-1.5 eq/min, or about 0.3-1.5 eq/min. In some embodiments, the second introduction rate may be about 0.05-1.3 eq/min, about 0.05-1.2 eq/min, about 0.05-1.0 eq/min, about 0.06-1.3 eq/min, about 0.06-1.2 eq/min, or about 0.06-1.0 eq/min. In some embodiments, the second shell precursor solution may be introduced after the introduction of the first shell precursor solution, and the first introduction rate is greater than or equal to the second introduction rate. In some embodiments, the second shell precursor solution may be introduced twice, wherein the first shell precursor solution is introduced between the two introductions of the second shell precursor solutions, and the first introduction rate is greater than or equal to the second introduction rate. In some embodiments, the first shell precursor solution and/or the second shell precursor solution may comprise materials that can form shells in subsequent stages. The shells may comprise a shell encapsulating the core in the quantum dot core solution and a cloud-like shell covering a portion of the quantum dot comprising the core and the shell above. The shells have the same materials as the core in the quantum dot core solution, or have materials with a relatively matched lattice. In some embodiments, the first shell precursor solution and/or the second shell precursor solution may comprise inorganic semiconductor materials of Group II, Group III, Group IV, Group V, Group VI, or a combination thereof.

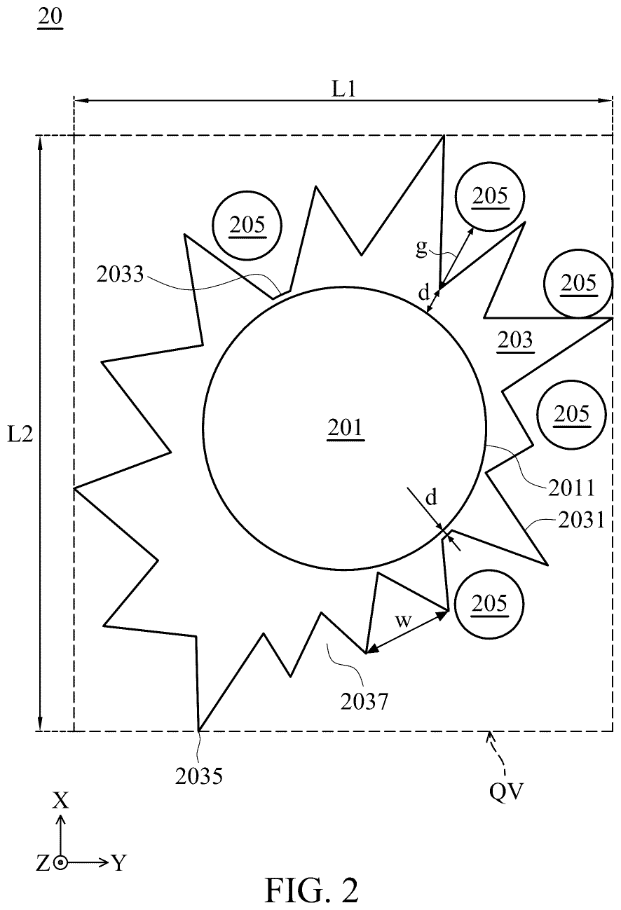

In the step S105, the quantum dot precursor solution obtained in the step S103 is heated at a first temperature to form a quantum dot solution comprising a plurality of quantum dots. In some embodiments, the first temperature is greater than or equal to 250° C. and less than or equal to 310° C. The quantum dots formed in the step S105 are quantum dots having a core-shell structure. Each of the quantum dots comprises a first shell and a second shell above the core surface of the core. The first shell is formed discontinuously around the core surface of the core. The second shell is formed between the core and the first shell to encapsulate the core surface. The second shell have an irregular outer surface. In some embodiments, the quantum dots formed in the step S105 have a core-shell structure as shown in FIG. 2.

FIG. 2 illustrates a schematic view of a quantum dot 20 according to some embodiments of the disclosure. As shown in FIG. 2, the quantum dot 20 has a core 201, a first shell 205, and a second shell 203. The core 201 has a core surface 2011, and the first shell 205 and the second shell 203 are above the core surface 2011. The first shell 205 is discontinuously around the core surface 2011. The second shell 203 having a continuous and irregular outer surface 2031 is formed between the core 201 and the first shell 205 to encapsulated the core surface 2011.

The core 201 is a light-emitting core of the quantum dot 20. In some embodiments, an average diameter of the core 201 is greater than or equal to 9 nm and less than or equal to 20 nm. In some embodiments, the core 201 may be composed of an inorganic conductor material or an inorganic semiconductor material. Examples of inorganic semiconductor materials may include, but are not limited to, semiconductor materials of Group II-VI, Group III-V, Group IV-VI, and/or Group IV. Specific examples of inorganic semiconductor materials comprise, but not limited to, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS HgZnSeTe, HgZnSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb InAlPAs, InAlPSb, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, CsPbX₃ or Cs₄PbX₆, in which X is chlorine, bromine, iodine or a combination thereof.

In some embodiments, the second shell 203 encapsulates the core 201 and directly contact the core surface 2011 of the core 201, but the disclosure is not limited thereto. In some embodiments, there is a gap between the second shell 203 and the core 201, and the second shell 203 is not directly contact the core surface 2011 of the core 201. The second shell 203 has an irregular concave-convex outer surface. That is, the second shell 203 has a plurality of regions with uneven thickness. The region where the thickness of the second shell 203 progressively decreased is defined as a recessed portion, and the region or point in the recessed portion where the thickness is thinnest is defined as a bottom of the recessed portion. The thickness range of the second shell 203 is greater than or equal to 0 nm and less than or equal to 5 nm. The region in the second shell 203 having a thickness of 0 nm indicates that there is no second shell 203 in this region. Therefore, the core surface 2011 corresponding to this region is not covered by the second shell 203 and thus exposed to the outside. In some embodiments, the second shell is greater than or equal to 0 nm and less than or equal to 4 nm, or greater than 0 nm and less than or equal to 3 nm. In some embodiments, the second shell 203 has one recessed portion. The recessed portion has a recessed width w, as shown in FIG. 2. In some embodiments, the recessed width w corresponds to a distance between two peaks in an region of the second shell 203 (the term “peak” indicates an region or point in the second shell 203 where the thickness of both sides of the region or point are less than that of the region or point). In embodiments where there are more than 2 recessed portions, the recessed widths of the recessed portions may be the same, or they may be different. As shown in FIG. 2, the second shell 203 has a plurality of recessed portions 2037, and each of the recessed portions 2307 has a recessed width w which may be the same or different than other recessed portions 2307. In some embodiments, the recessed width w is greater than 0 nm and less than or equal to 10 nm. In some embodiments, the recessed width w is greater than 0 nm and less than or equal to 7 nm, greater than 0 nm and less than or equal to 5 nm, or greater than 0 nm and less than or equal to 3 nm. Furthermore, the recessed portion has a recessed bottom. The recessed bottom is a region or point in the recessed portion where the thickness of the second shell 203 is thinnest. There is a distance d between the recessed bottom and the core surface 2011. In embodiments where there are more than 2 recessed portions, the distances d between the recessed bottoms of the recessed portions and the core surface 2011 may be the same, or they may be different from one another, as shown in FIG. 2. Among the recessed bottoms of the recessed portion of the second shell 203, the recessed portion in which the distance d between the recessed bottom thereof and the core surface 2011 is shortest is defined as a lowest point 2033 of the second shell 203. In embodiments where the thickness of the second shell 203 is 0, the distance d between the recessed bottom of the recessed portion and the core surface 2011 is 0. The thickest region or point in the second shell 203 is defined as a highest point 2035. In some embodiments, the outer surface of the second shell 203 is a concave-convex outer surface, and there is a height difference between the lowest point 2033 and the highest point 2035 of the concave-convex outer surface, wherein the height difference is greater than 0 nm and less than or equal to 5 nm.

The first shell 205 may be discontinuously distributed around the core surface 2011 of the core 201, and the second shell 203 may be between the core 201 and the first shell 205, but the disclosure is not limited thereto. In some embodiments, there may be no second shell 203 between the core 201 and the first shell 205 in some regions. In some embodiments, there may be a gap g between the first shell 205 and the outer surface 2031 of the second shell 203, and the first shell 205 is discontinuously distributed around the second shell 203, but the disclosure is not limited thereto. In the embodiment in which the thickness of the second shell 203 is 0, the gap g is a gap between the core surface 2011 of the core 201 and the first shell 205. The first shell 205 may be discontinuously distributed around the core surface 2011. The gaps g may be the same, or they may be different from one another. The gap g may be greater than or equal to 0 nm and less than or equal to 10 nm. In some embodiments, the gap g is greater than or equal to 0 nm and less than or equal to 7 nm, greater than or equal to 0 nm and less than or equal to 5 nm, or greater than or equal to 0 nm and less than or equal to 3 nm.

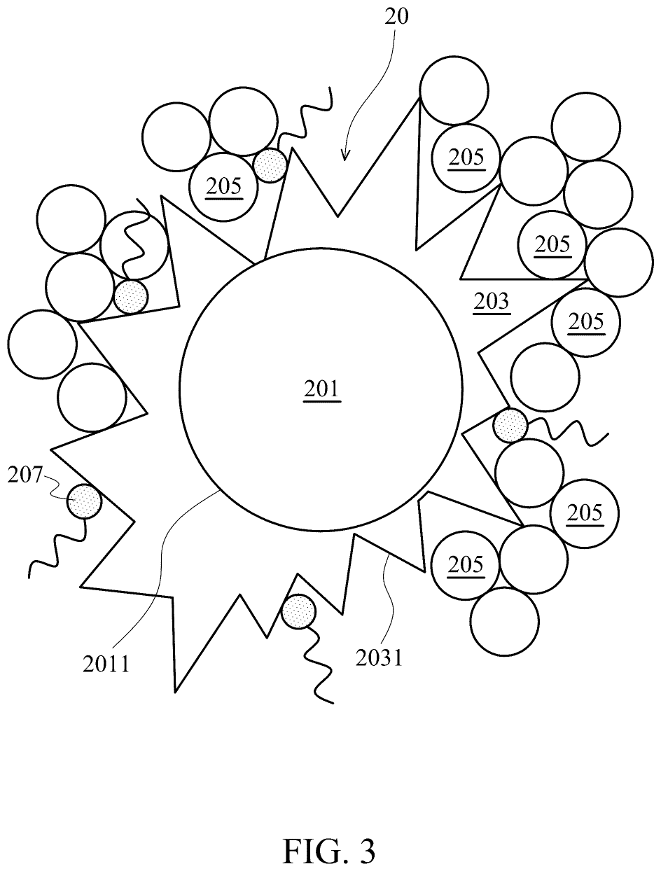

In some embodiments, the first shell 205 may have a particle-like structure. In this embodiment, the first shell 205 may comprise a plurality of particles around the core 201 and the second shell 203. In some embodiments, some of the particles of the first shell 205 may be stacked on top of each other, as shown in FIG. 3. In some embodiments, there are 4 or fewer stacked particles in the first shell 205. In some embodiments, there are 3 or fewer stacked particles in the first shell 205. In this embodiment, the average diameter of the particles of the first shell 205 is greater than 0 nm and less than or equal to 5 nm. For example, in some embodiments, the average diameter of the particles of the first shell 205 is greater than or equal to 1 nm and less than or equal to 5 nm, greater than or equal to 1 nm and less than or equal to 4 nm, greater than or equal to 2 nm and less than or equal to 5 nm, or greater than or equal to 2 nm and less than or equal to 4 nm. FIG. 2 shows an embodiment in which the first shell 205 comprises a plurality of particles. In this embodiment, the gaps g between the regions of the outer surface 2031 of the second shell 203 and the particles comprised in the first shell 205 may be the same, or they may be different from one another.

In some embodiments, the sum of the thickness of the first shell 205 and the second shell 203 and the gap g is greater than 0 nm and less than or equal to 35 nm, for example, the sum is greater than 0 nm and less than or equal to 30 nm, greater than 0 nm and less than or equal to 25 nm, greater than 0 nm and less than or equal to 20 nm, greater than or equal to 1 nm and less than or equal to 25 nm, greater than or equal to 2 nm and less than or equal to 25 nm, greater than or equal to 5 nm and less than or equal to 25 nm. In the embodiment, when the first shell 205 comprises a plurality of particles, for example, 4 particles in the first shell 205, the sum of the thickness of the first shell 205, the second shell 203, and the gap g is greater than 0 nm and less than or equal to 35 nm. When there are 3 particles in the first shell 205, the sum of the thickness of the first shell 205, the second shell 203 and the gap g is greater than 0 nm and less than or equal to 30 nm. When there are 2 particles in the first shell 205, the sum of the thickness of the first shell 205, the second shell 203 and the gap g is greater than 0 nm and less than or equal to 25 nm. When there is 1 particle in the first shell 205, the sum of the thickness of the first shell 205, the second shell 203 and the gap g is greater than 0 nm and less than or equal to 20 nm. In some embodiments, the first shell 205 and the second shell 203 may be made of the same materials as the core 201 or made of materials that have a lattice that matches the lattice of the materials of the core 201. In some embodiments, the first shell 205 and the second shell 203 may be made of the same materials.

Since the first shell 205 of the quantum dot 20 is discontinuously distributed around the core surface 2011 of the core 201 and the second shell 203 has an irregularly shaped outer surface 2031, the quantum dot 20 also has an irregular surface. In some embodiments, the quantum dot 20 has a maximum diameter and a minimum diameter. The expression “maximum diameter” of the quantum dot 20 indicates the longest length of a smallest virtual box encapsulating the quantum dot 20. As shown in FIG. 2, the maximum diameter of the quantum dot 20 is the longest length among a length (diameter) L1 in the Y direction, a length (diameter) L2 in the X direction, and a length in the Z direction (not shown) of the smallest virtual box QV encapsulating the quantum dot 20. In more detail, the maximum diameter L1 and/or L2 comprises the maximum diameter of the core 201, the maximum thickness of the second shell 203, the maximum gap between the first shell 205 and the second shell 203, and the maximum diameter of the first shell 205. The expression “maximum diameter of the first shell” refers to the sum of the maximum diameters of the stacked N first shell 205. When N is less than or equal to 4, the maximum diameter L1 and/or L2 may be larger than or equal to 30 nm and smaller than or equal to 90 nm. When N is less than or equal to 3, the maximum diameter L1 and/or L2 may be larger than or equal to 30 nm and smaller than or equal to 80 nm. When N is less than or equal to 2, the maximum diameter L1 and/or L2 may be larger than or equal to 30 nm and smaller than or equal to 70 nm. When N is less than or equal to 1, the maximum diameter L1 and/or L2 may be larger than or equal to 30 nm and smaller than or equal to 60 nm. The expression “minimum diameter” of the quantum dot 20 indicates the shortest length of a smallest virtual box encapsulating the quantum dot 20. As shown in FIG. 2, the minimum diameter of the quantum dot 20 is the shortest length among a length (diameter) L1 in the Y direction, a length (diameter) L2 in the X direction, and a length in the Z direction (not shown) of the smallest virtual box QV encapsulating the quantum dot 20. The minimum diameter L1 and/or L2 comprises the minimum diameter of the core 201 and the minimum thickness of the second shell 203. Therefore, the minimum diameter L1 and/or L2 may be larger than 9 nm.

FIG. 3 illustrates a schematic view of a quantum dot 20 according to some embodiments of the disclosure. As shown in FIG. 3, ligands 207 are distributed around the quantum dot 20. The ligands 207 may be around the outer surface 2031 of the second shell 203 and/or in the gap g, as shown in FIG. 3. The ligands 207 can further enhance the steric hindrance of the surface of the quantum dot 20 to enhance the ability to trap the environmental damage factors in the exterior of the quantum dot 20 or the ligands 207 or trap the environmental damage factors between the quantum dot 20 and the ligands 207. Therefore, the resistance or tolerance of the quantum dots 20 to the environmental damage factors could be enhanced, or the reliability or luminous life of the quantum dots 20 could be further enhanced by the ligands 207. The ligands 207 may comprise a polar ligand or a non-polar ligand. Examples of the ligands 207 may comprise alkylphosphines, alkylamines, arylamines, pyridines, fatty acids, thiophenes, thiol compounds, carbene compounds, or a combination thereof. Examples of the fatty acids may include oleyl acid, stearic acid, lauric acid, or a combination thereof. Examples of alkylamines may include oleyl amine, octyl amine, dioctyl amine, hexadecyl amine, or a combination thereof. Examples of carbene compounds may include 1-octadecene. Examples of alkylphosphines may include trioctylphosphine. In some embodiments, the length of each of the ligands 207 may be about 1-2.5 nm, about 1.2-2.3 nm, about 1.3-2.0 nm, or about 1.5-1.9 nm.

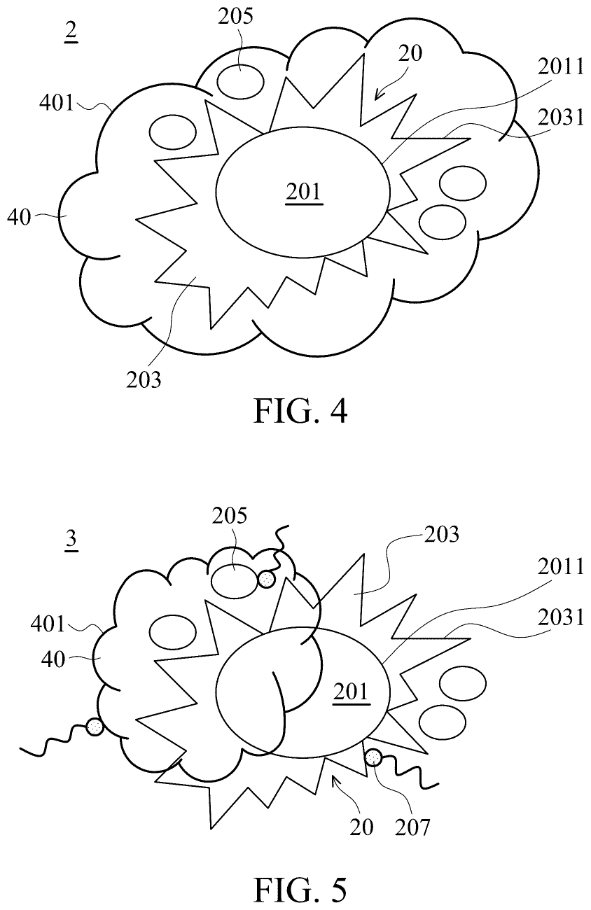

In the step S107, the quantum dot solution comprising the plurality of quantum dots 20 is stirred at second temperature to form a first quantum dot structure. In some embodiments, the second temperature is greater than or equal to the first temperature. In some embodiments, the second temperature is equal to the first temperature. In some embodiments, the second temperature is greater than or equal to 250° C. and less than or equal to 310° C. In the step S107, the quantum dot solution is stirred at a stirring rate of about 10-90 rpm for about 10-60 minutes. In some embodiments, the stirring rate may be about 20-80 rpm, about 30-70 rpm, about 40-60 rpm, or about 50 rpm. In some embodiments, the stirring may last for about 10-60 minutes, about 15-50 minutes, about 20-40 minutes, or about 30 minutes. The resulting first quantum dot structure has a cloud-like shell covering a portion of the quantum dot, as shown in FIG. 4.

FIG. 4 illustrates a schematic view of a first quantum dot structure 2 according to some embodiments of the disclosure. The first quantum dot structure 2 comprises the quantum dot 20 and the cloud-like shell 40. The cloud-like shell 40 covers a portion of the quantum dot 20 and has an irregular outer surface 401. In some embodiments, the cloud-like shell 40 is made of the same materials as the core 201, or of materials that have a lattice that matches the lattice of the materials of the core 201. In some embodiments, the cloud-like shell 40 may be made of the same materials as the first shell 205 and the second shell 203.

In some embodiments of the disclosure, a projection of the quantum dot 20 onto a plane has a maximum width in a first direction and a maximum length in a second direction perpendicular to the first direction. A projection of the cloud-like shell 40 onto the plane and the projection of the quantum dot 20 onto the plane overlap in an overlapping region. An area of the overlapping region conforms to the following formula: maximum width*maximum length area of the overlapping region ¼*maximum width*maximum length.

For example, referring to FIG. 2, the extending direction of the maximum diameter of the quantum dot 20 is defined as the first direction, and the direction perpendicular to the first direction is defined as the second direction. Based on a plane defined by the first direction and the second direction, the projection of the quantum dot 20 onto the plane has a maximum width in the first direction and a maximum length in a second direction perpendicular to the first direction. In an embodiment, the first direction is Y direction and the second direction is X direction, the maximum width of the quantum dot 20 is a length of a projection of the maximum diameter L1 of the quantum dot 20 onto the XY plane in the Y direction, and the maximum length is a length of a projection of the maximum diameter L2 of the quantum dot 20 onto the XY plane in the X direction. The cloud-like shell 40 covers a portion of the quantum dot 20 which means that the projection of the cloud-like shell 40 onto the plane defined by the first direction and the second direction partially overlaps the projection of the quantum dot 20 onto the plane. In some embodiments, the projection of the cloud-like shell 40 overlaps with the projection of the quantum dots 20 onto the plane in an overlapping region, and an area of the overlapping region conforms to the following formula:

maximum width*maximum length≥area of the overlapping region≥¼*maximum width*maximum length.

In some embodiments, the cloud-like shell 40 directly contacts the first shell 205 of the quantum dot 20 and the second shell 203 of the quantum dot 20, but the disclosure is not limited thereto. In some embodiments, there is a first gap between the cloud-like shell 40 and the first shell 205 of the quantum dot 20, and there is a second gap between the cloud-like shell 40 and the second shell 203.

In some embodiments, an outer surface 401 of the cloud-like shell 40 is a continuously concave-convex outer surface. In some embodiments, there is a height difference between the lowest point and the highest point of the cloud-like shell 40. The definitions of the lowest point, the highest point, and the height difference of the cloud-like shell 40 are similar to the definitions of the lowest point, the highest point, and the height difference of the second shell 203, so they will not be repeated here. In some embodiments, the outer surface of the cloud-like shell 40 has a different surface profile than the outer surface of the second shell 203. In some embodiments, the height difference between the lowest point and the highest point of the cloud-like shell 40 is less than or equal to the height difference between the lowest point and the highest point of the second shell 203. In some embodiments, the height difference between the lowest point and the highest point of the cloud-like shell 40 is not 0.

The first quantum dot structure 2 comprising the quantum dot 20 and the cloud-like shell 40 can be obtained after the completion of the step S107. In some embodiments, the projection of the first quantum dot structure 2 onto a plane defined by the first direction and the second direction has a structure width in the first direction and a structure length in the second direction. The structure width may be greater than 9 nm and less than or equal to 1.5*maximum width. The structure length can be greater than 9 nm and less than or equal to 1.5*maximum length.

In some embodiments, the method of forming quantum dot structures according to some embodiments of the disclosure may further comprise a purification step S109. In some embodiments, the purification step S109 may comprise a purification process of washing with an organic solvent and then centrifuging the solution containing the quantum dot structures to obtain purified quantum dot structures.

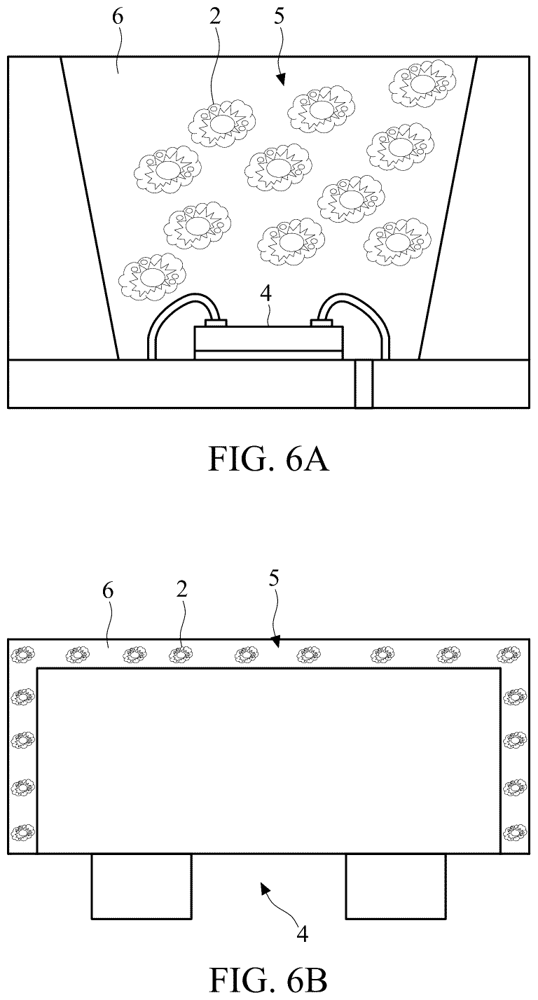

In some embodiments, the quantum dot structure may further comprise ligands 207 above the surfaces of the first shell 205, the second shell 203 and/or the cloud-like shell 40, as shown in FIG. 5. FIG. 5 illustrates a schematic view of a second quantum dot structure 3 according to some embodiments of the disclosure. The second quantum dot structure 3 comprises the quantum dot 20 mentioned above, a cloud-like shell 40 covering a portion of the quantum dot 20, and ligands 207 above surfaces of the first shell 205, the second shell 203 and/or the cloud-like shell 40. In some embodiments, the ligands 207 directly contact the first shell 205, the outer surface 2031 of the second shell 203 and/or the outer surface 401 of the cloud-like shell 40. The ligands 207 shown in FIG. 5 is substantially the same as the ligands 207 in FIG. 3, so the description will not be repeated here. The ligands 207 can further enhance the steric hindrance of the surface of the quantum dot stricture 3, enhance the resistance or tolerance of the quantum dot stricture 3 to the environmental damage factors, and/or enhanced the reliability or luminous life of the quantum dot stricture 3.

The first quantum dot structure 2 or the second quantum dot structure 3 mentioned above may be applied in a light-emitting device to provide a light-emitting device with better reliability and service life. According to another aspect of the disclosure, the disclosure further provides a light-emitting device, which comprises a light source emitting a first light and a wavelength conversion portion that absorbs part of the first light and converts it into a second light, wherein the wavelength conversion portion comprises the first quantum dot structure 2 and/or the second quantum dot structure 3 mentioned above. In some embodiments, the wavelength conversion portion may further comprise other phosphors. In addition, materials of the core 201 of the quantum dot 20 may be selected according to the required light color (such as white light, red light, blue light, green light). Therefore, the light-emitting device can be used in various fields, such as a lighting, an automotive central control panel and an instrument panel, a backlight unit for a display, RGB pixels of an LED display.

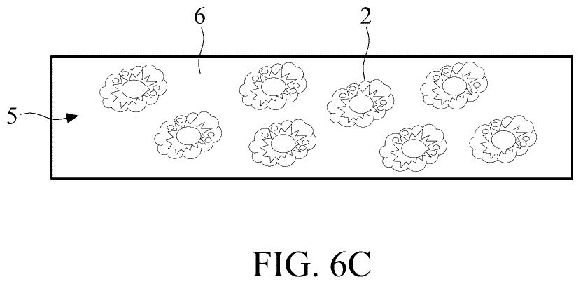

FIG. 6A illustrates a schematic view of a light-emitting device according to some embodiments of the disclosure. As shown in FIG. 6A, the light-emitting device is an LED light-emitting device, which comprises a light source 4 and a wavelength conversion portion 5. The light source 4 may be a light-emitting diode chip, which can emit a first light having a first wavelength (such as blue light or UV light). In some embodiments, the light-emitting diode chip comprises a submillimeter light-emitting diode (mini LED) chip and a micro light-emitting diode (micro LED) chip. The wavelength conversion portion 5 can absorb part of the first light emitted by the light source 4 and convert the absorbed first light into a second light having a second wavelength. In some embodiments, the first wavelength is different from the second wavelength. The wavelength conversion portion 5 may comprise a matrix 6 and the first quantum dot structures 2 uniformly dispersed in the matrix 6, but the disclosure is not limited thereto. In some embodiments, part or all of the first quantum dot structure 2 in the wavelength conversion portion 5 can be replaced by the second quantum dot structures 3 above. The matrix 6 may comprise a transparent resin, such as acrylate resins, organosiloxane resins, acrylate-modified polyurethanes, acrylate-modified silicone resins or epoxy resins. In some embodiments, the wavelength conversion portion 5 may further comprise diffusion particles uniformly dispersed in the matrix 6. The diffusion particles can scatter the first light incidented into the matrix 6 to increase the path of the first light passing through the wavelength conversion portion 5. The diffusion particles may comprise inorganic particles, organic polymer particles, or a combination thereof. Examples of the inorganic particles comprise silicon oxides, titanium oxides, aluminum oxides, calcium carbonates, barium sulfates, or a combination thereof. Examples of the organic polymer particles comprise polymethyl methacrylates (PMMA), polystyrenes (PS), acrylonitrile-butadiene-styrene copolymers (ABS), polyurethanes (PU), or a combination thereof.

In some embodiments, the light-emitting device may be a white light-emitting device. As shown in FIG. 6A, in an embodiment, the light source 4 may be a blue LED chip, and the wavelength conversion portion 5 may comprise first red quantum dot structures 2 and first green quantum dot structures 2, wherein the first red quantum dot structures 2 contain red quantum dots 20, the first green quantum dot structures 2 contain green quantum dots 20. In another embodiment, the light source 4 may be a UV LED chip, and the wavelength conversion portion 5 may comprise first red, green, and blue quantum dot structures 2, wherein the first red quantum dot structures 2 contain red quantum dots 20, the first green quantum dot structures 2 contain green quantum dots 20 and the first blue quantum dot structures 2 contain blue quantum dots 20. In some embodiments, part or all of the first quantum dot structures 2 in the wavelength conversion portion 5 may be replaced by the second quantum dot structures 3 mentioned above. In some embodiments, the light-emitting device can emit a monocolor light, such as a red light, a green light or a blue light. The light-emitting device emitting a red light may comprise first red quantum dot structures 2 or second red quantum dot structures 3 and a light source 4 emitting a blue light or a UV light. In this embodiment, the light source 4 may be an LED chip, and the blue light or the UV light from the light-emitting diode chip can excite the first red quantum dot structures 2 or the second red quantum dot structures 3 to emit a red light. The light-emitting device that emits a green light may comprise first green quantum dot structures 2 or second green quantum dot structures 3 and a light source 4 that emits a blue light or a UV light. In this embodiment, the light source 4 may be an LED chip, and the blue light or the UV light from the LED chip can excite the first green quantum dot structures 2 or the second green quantum dot structures 3 to emit a green light. The blue light-emitting device may comprise first blue quantum dot structures 2 or second blue quantum dot structures 3 and a light source 4 emitting a blue light or a UV light. In this embodiment, the light source 4 may be a light-emitting diode chip, and the blue light or the UV light from the light-emitting diode chip can excite the first blue quantum dot structures 2 or the second blue quantum dot structures 3 to emit a blue light. The red light-emitting device, green light-emitting device and blue light-emitting device mentioned above can be used as pixels in a light-emitting diode display or a micro light-emitting diode display.

FIG. 6B illustrates a schematic view of a light-emitting device according to some embodiments of the disclosure. As shown in FIG. 6B, the light-emitting device may be a chip-level package (CSP), wherein the light source 4 may be a flip-chip LED chip, and the wavelength conversion portion 5 may comprise a quantum dot film comprising first quantum dot structures 2, second quantum dot structures 3, or a combination thereof. The quantum dot film may cover a top surface and side surfaces of the light source 4, as shown in FIG. 6B. In other embodiments, the quantum dot film covers the top surface of the light source 4. In some embodiments, the LED chip comprises a mini LED chip and a micro LED chip.

In some embodiments, the light-emitting device may be a chip-level package (CSP) emitting white light. As shown in FIG. 6B, in an embodiment, the light-emitting device may be a chip-level package (CSP), wherein the light source 4 may be a flip-chip blue LED chip. The wavelength conversion portion 5 may be a quantum dot film covering a top surface and side surfaces of the light source 4 or the top surface of the light source 4. The quantum dot film may comprise first red, green, and blue quantum dot structures 2, wherein the first red quantum dot structures 2 comprise red quantum dots 20, the first green quantum dot structures 2 comprise green quantum dots 20, and the first blue quantum dot structures 2 comprise blue quantum dots 20. Part or all of the first quantum dot structures 2 in the quantum dot film may be replaced by the second quantum dot structures 3 mentioned above. In some embodiments, the light-emitting device may be a chip-level package light-emitting device emitting a monocolor light, such as a red light, a green light or a blue light. The light-emitting device emitting a red light may comprise a quantum dot film comprising first red quantum dot structures 2 or second red quantum dot structures 3 and a light source 4 emitting a blue light or a UV light. In this embodiment, the light source 4 may be a light-emitting diode chip, and the blue light or the UV light from the light-emitting diode chip can excite the first red quantum dot structure 2 or the second red quantum dot structures 3 to emit a red light. The light-emitting device that emits a green light may comprise a quantum dot film comprising first green quantum dot structures 2 or the second green quantum dot structures 3 and a light source 4 that emits a blue light or a UV light. In this embodiment, the light source 4 may be a light-emitting diode chip, and the blue light or the UV light from the light-emitting diode chip can excite the first green quantum dot structures 2 or the second green quantum dot structures 3 to emit a green light. The blue light-emitting device may comprise a quantum dot film comprising first blue quantum dot structures 2 or second blue quantum dot structures 3 and a light source 4 emitting a blue light or a UV light. In this embodiment, the light source 4 may be a light-emitting diode chip, and the blue light or the UV light from the light-emitting diode chip can excite the first blue quantum dot structures 2 or second blue quantum dot structures 3 to emit a blue light. The red chip-level package light-emitting device, green chip-level package light-emitting device and blue chip-level package light-emitting device mentioned above can be used as pixels in an LED display or a micro LED display.

In some embodiments, the micro LED display may comprise a plurality of red light-emitting devices, green light-emitting devices and/or blue light-emitting devices as shown in FIG. 6A or FIG. 6B. In some embodiments, the blue light-emitting device of the micro LED display may comprise a blue micro LED chip without the wavelength conversion portion 5.

In some embodiments, in addition to the first quantum dot structures 2 and/or the second quantum dot structures 3, the wavelength conversion portion 5 may further comprise other phosphors. In one embodiment, the wavelength conversion portion 5 may comprise first red quantum dot structures 2 and green phosphors, wherein the green phosphor powders may be, for example, aluminum garnet (LuAG) phosphors, yttrium aluminum garnet (YAG) phosphors, SiAlON (β-SiAlON) phosphors, silicate phosphors. In another embodiment, the wavelength conversion portion 5 may comprise first green quantum dot structures 2 and red phosphors, wherein the red phosphors may be (Sr, Ca)AlSiN₃:Eu²⁺, Ca₂Si₅N₈:Eu²⁺, Sr(LiAl₃N₄):Eu²⁺, manganese doped red fluoride phosphors (such as K₂GeF₆:Mn⁴⁺, K₂SiF₆:Mn⁴⁺, K₂TiF₆:Mn⁴⁺, etc.), but not limited thereto.

The disclosure provides a backlight unit comprising a plurality of the white light-emitting devices. The disclosure provides a display comprising the backlight unit. In some embodiments, the display is a liquid crystal display.

In some embodiments, the wavelength conversion portion 5 may be a quantum dot layer (QD layer), as shown in FIG. 6C. FIG. 6C illustrates a schematic view of a wavelength conversion portion 5 according to some embodiments of the disclosure, wherein the wavelength conversion portion 5 is a quantum dot layer. The quantum dot layer may comprise a transparent matrix 6 and first quantum dot structures 2, and part or all of the first quantum dot structures 2 may be replaced by the second quantum dot structures 3. The transparent matrix 6 may comprise acrylic resins, organosiloxane resins, acrylate-modified polyurethanes, acrylate-modified silicone resins or epoxy resins. In some embodiments, the quantum dot layer may be applied to a backlight unit for a display. In some embodiments, the backlight unit provides white light, wherein the backlight unit comprises a quantum dot layer and a light panel comprising a plurality of blue light-emitting diode chips. The quantum dot layer comprises first green and red quantum dot structures 2, or second green and red quantum dot structures 3, or a combination thereof. Similarly, as mentioned above, the quantum dot layer may comprise other phosphors which would be mixed with the quantum dot structures according to requirements.

In order to make the above and other purposes, features, and advantages of the disclosure more apparent and understandable, several example and comparative examples of preparing quantum dots and quantum dot structures are given below. In these examples, the quantum dots and the quantum dot structures are used to prepare light-emitting devices. The light-emitting devices are burned in a general environment without blocking moisture and oxygen and in a nitrogen environment without moisture and oxygen to observe the tolerance and reliability of the quantum dots and the quantum dot structures to oxygen or moisture. These examples may specify the properties of the quantum dot structures formed by the method of forming quantum dot structures according to some embodiments of the disclosure, the effects achieved by the quantum dot structures according to some embodiments of the disclosure, and the properties of the light-emitting devices according to some embodiments of the disclosure. The following examples and comparative examples are for illustrative purposes only and should not be construed as limitations on the implementation of this disclosure.

[Preparation of Core Solution]

<First Core Precursor Solution>

64 mg of cadmium oxide (CdO), 1615 mg of zinc oxide (ZnO), 20 mL of oleic acid (OA) and 80 mL of 1-octadecene (ODE) were placed in a 250 mL three-necked round-bottom flask to form a mixture. The mixture was heated at 150° C. for about 120 min while pumping at 100 mTorr, and nitrogen or inert gas was introduced into the three-necked flask to obtain 4 equivalents of cadmium-zinc (Cd—Zn) solution as the first core precursor solution.

<Second Core Precursor Solution>

655 mg of selenium (Se) powder, 148 mg of sulfur (S) powder, and 8 g of trioctylphosphine (TOP) were placed in a beaker to obtain a mixture, stirred and clarified, and sealed with nitrogen to obtain a selenium-sulfur mixture as a second core precursor solution.

[Preparation of Shell Precursor Solution]

<First Shell Precursor Solution>

5.6 g of anhydrous zinc acetate, 4 g of oleic acid (OA), and 20 g of 1-octadecene (ODE) were placed in a 50 mL three-necked round-bottom flask, heated to 150° C. for about 30 min, clarified, and then sealed with nitrogen to obtain a 0.7 equivalent of Zn-OA solution as the first shell precursor solution.

<Second Shell Precursor Solution>

352 mg of sulfur powder and 5.5 g of trioctylphosphine (TOP) were placed in a beaker, stirred and clarified, and sealed by passing nitrogen to obtain 1 equivalent of S-TOP solution as a second shell precursor solution.

[Preparation of Comparative Quantum Dot 1]

1 equivalent of the first core precursor solution was heated to 280° C. and reacted for 3 minutes. 1 equivalent of the second core precursor solution was introduced into the heated first core precursor solution and then heated to 320° C. and reacted for 10 minutes to form a core solution. The second shell precursor solution was introduced into the core solution and reacted for 10 minutes. Then, the core solution was cooled to 250° C. 1 equivalent of the first shell precursor solution was fast introduced into the core solution. 1 equivalent of the second shell precursor solution was fast introduced into the core solution to obtain a quantum dot precursor solution. The quantum dot precursor solution was heated at 250° C. for 20 minutes to synthesize quantum dots. The solution containing the quantum dots was cooled to room temperature and washed with 100 mL of methanol/80 mL of toluene for four times, and then the quantum dot solution was centrifuged to obtain the purified comparative quantum dots 1.

[Preparation of Comparative Quantum Dot 2]

1 equivalent of the first core precursor solution was heated to 280° C. and reacted for 3 minutes. 1 equivalent of the second core precursor solution was introduced into the heated first core precursor solution and then heated to 320° C. and reacted for 10 minutes to form a core solution. The second shell precursor solution was introduced into the core solution and reacted for 10 minutes. Then, the core solution was cooled to 250° C. 1 equivalent of the first shell precursor solution was introduced into the core solution at an introduction rate of 0.38 eq/min. 1 equivalent of the second shell precursor solution was introduced into the core solution at an introduction rate of 0.9 eq/min to obtain a quantum dot precursor solution. The quantum dot precursor solution was heated at 250° C. for 60 minutes to synthesize quantum dots. The solution containing the quantum dots was cooled to room temperature and washed with 100 mL of methanol/80 mL of toluene for four times, and then the quantum dot solution was centrifuged to obtain the purified comparative quantum dots 2.

[Preparation of Quantum Dot Structure]

1 equivalent of the first core precursor solution was heated to 280° C. and reacted for 3 minutes. 1 equivalent of the second core precursor solution was introduced into the heated first core precursor solution and then heated to 320° C. and reacted for 10 minutes to form a core solution. The second shell precursor solution was introduced into the core solution and reacted for 10 minutes. Then, the core solution was cooled to 250° C. 1 equivalent of the first shell precursor solution was introduced into the core solution at an introduction rate of 0.38 eq/min. 1 equivalent of the second shell precursor solution was introduced into the core solution at an introduction rate of 0.9 eq/min to obtain a quantum dot precursor solution. The quantum dot precursor solution was heated at 250° C. for 60 minutes to synthesize a quantum dot solution comprising quantum dots. Put a magnet in the quantum dot solution to stir the quantum dot solution at 50 rpm for 15 minutes at 250° C. The stirred quantum dot solution was stand for 30 minutes to form a quantum dot structure solution comprising quantum dot structures. The quantum dot structure solution was cooled to room temperature and washed with 100 mL of methanol/80 mL of toluene for four times, and then the quantum dot structure solution was centrifuged to obtain the purified quantum dot structures.

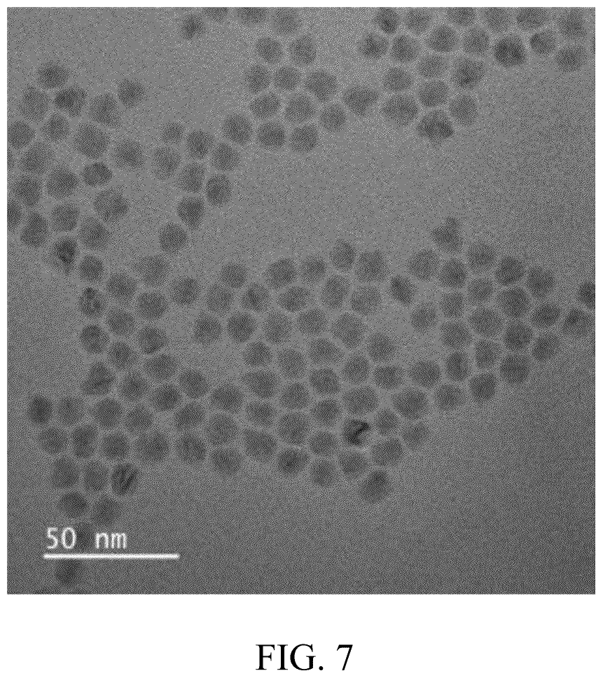

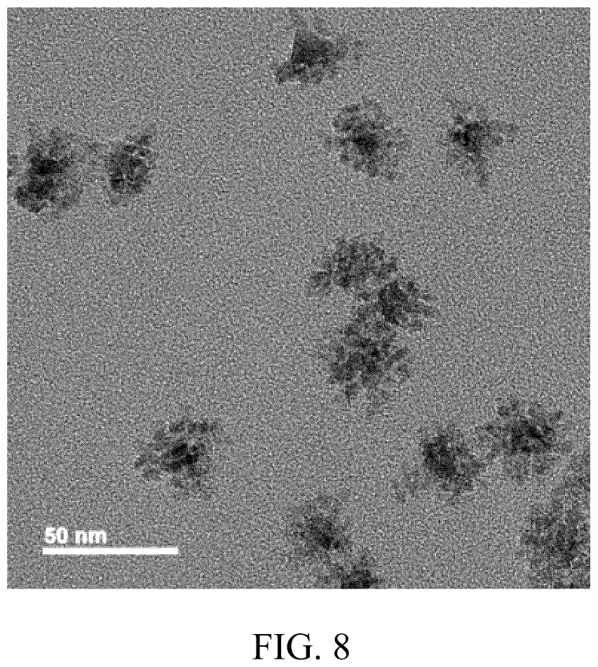

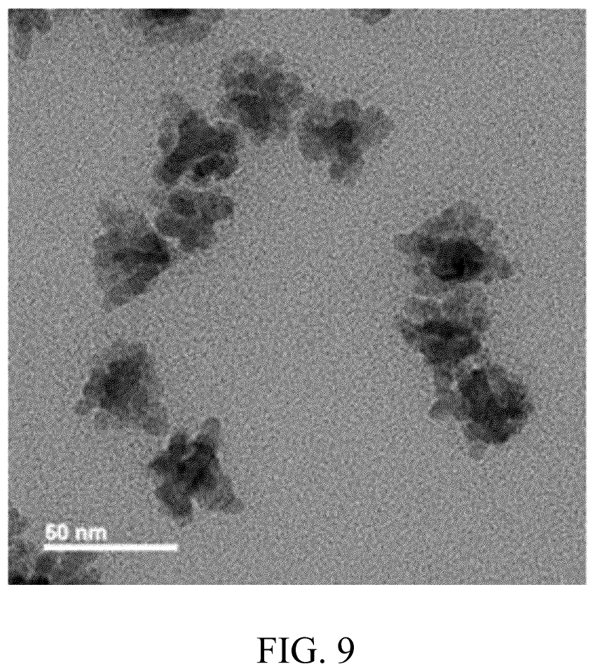

The structures of the comparative quantum dot 1, the comparative quantum dot 2 and the quantum dot structure were analyzed by a transmission electron microscope (TEM, manufactured by JEOL, Japan, model JEM-2100F). FIG. 7 is a transmission electron microscope (TEM) image of the comparative quantum dot 1 according to some embodiments of the disclosure. FIG. 8 is a TEM image of the comparative quantum dot 2 according to some embodiments of the disclosure. FIG. 9 is a TEM image of the quantum dot structures according to some embodiments of the disclosure. The maximum diameters of the comparative quantum dot 1, the comparative quantum dot 2 and the quantum dot structure were averaged over a random sample of 50 comparative quantum dots 1, 50 comparative quantum dots 2 and 50 quantum dot structures, respectively. The quantum efficiencies of the comparative quantum dot 1, the comparative quantum dot 2 and the quantum dot structure were measured by a fluorescence spectrometer (Fluoromax-4 Spectrofluorometer). The maximum diameters and quantum efficiencies of the comparative quantum dot 1, the comparative quantum dot 2 and the quantum dot structure are shown in Table 1 below.

TABLE 1

| | Comparative | Comparative | Quantum Dot |
|---|---|---|---|
| | Quantum Dot 1 | Quantum Dot 2 | Structure |
| Maximum diameter | 11.6 ± 1.6 | 23.7 ± 3.5 | 32.8 ± 3.3 |
| (nm) | | | |
| Quantum efficiency | 65 | 70 | 60 |
| (%) | | | |

As can be seen from Table 1, the average maximum diameter of the quantum dot structure of the embodiment of the disclosure is about 2.2 to 3.6 times of that of the comparative example quantum dot 1, and the average maximum diameter of the quantum dot structure of the embodiment of the disclosure is about 1.1 to 1.8 times of that of the comparative quantum dot 2. The quantum efficiencies of the quantum dot structure and comparative quantum dots 1 and 2 are all greater than about 60%.

[Preparation of Light-Emitting Devices]

The comparative quantum dot 1, the comparative quantum dot 2 and the quantum dot structure were coated on a blue light-emitting diode chip with a wavelength of about 450-460 nm, an optical power of about 34.6 mW and a wafer size of about 0.35*0.70 mm after mixed with an organosilicone resin to obtain a light-emitting device of the embodiment and light-emitting devices of Comparative Example 1 and 2. The light-emitting device of Comparative Example 1 comprises comparative quantum dots 1 and the light-emitting device of Comparative Example 2 comprises comparative quantum dots 2.

[Performance Testing of Light-Emitting Devices]

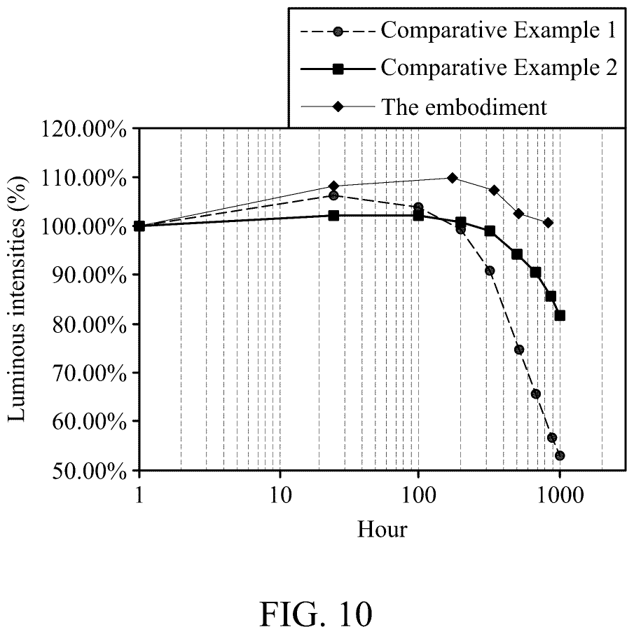

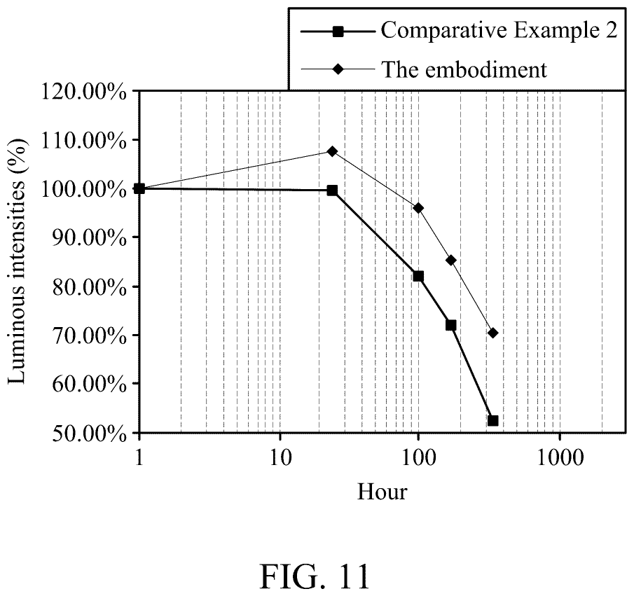

The light-emitting device of the embodiment and the light-emitting devices of Comparative Examples were lit at a current of 20 mA, a drive voltage of 3.0 V, and a continuous lighting current of 15 mA for about 1000 hours in a nitrogen environment without water and oxygen and for 300 hours in a general environment without blocking moisture and oxygen. The degree of luminous intensities of light-emitting device of the embodiment and the light-emitting devices of Comparative Examples which decay over time were measured by a luminance measuring instrument (WeiMin Industrial/Model 6122) and the resulting data was used to produce folding line diagrams as shown in FIGS. 10 and 11. FIG. 10 is a folding line diagram which shows the luminescence intensities of the light-emitting devices of the embodiment and Comparative Examples of the disclosure in a nitrogen environment as a function of time. FIG. 11 is a folding line diagram which shows the luminescence intensities of the light-emitting devices of the embodiment and Comparative Example of the disclosure in a general environment as a function of time.

As can be seen in FIG. 10, compared with the initial luminous intensity of the light-emitting device of Comparative Example 1, the luminous intensity of the light-emitting device of Comparative Example 1 is reduced by about 50% after 1000 hours of lighting in a nitrogen environment. Compared with the initial luminous intensity of the light-emitting device of Comparative Example 2, the luminous intensity of the light-emitting device of Comparative Example 2 is reduced by about 20% after 1000 hours of lighting in a nitrogen environment. Compared with the initial luminous intensity of the light-emitting device of the embodiment, the luminous intensity of the light-emitting device of the embodiment is reduced less than about 5% after 1000 hours of lighting in a nitrogen environment. From the above experimental results, it is obvious that the light-emitting device of the embodiment has better reliability or longer luminous life than the light-emitting devices of Comparative Examples, whether in a nitrogen environment or a general environment. In other words, compared with the quantum dots of Comparative Examples, the quantum dot structures of the disclosure have higher resistance to or better tolerance to the damage factors in the environment. Therefore, the quantum dot structure of the disclosure has better reliability or longer luminous life.

The components of the embodiments are outlined above so that those having ordinary knowledge in the art to which the present disclosure belongs may better understand the perspective of the embodiments of the present disclosure. Those having ordinary knowledge in the art to which the present disclosure belongs should understand that they can design or modify other processes or structures based on the embodiments of the present disclosure to achieve the same purposes and/or advantages as the embodiments described herein. Those having ordinary knowledge in the art to which the present disclosure belongs should also understand that such equivalent structures are not inconsistent with the spirit and scope of this disclosure, and that they can make various changes, substitutions, and replacements without violating the spirit and scope of this disclosure. Therefore, the scope of protection of this disclosure is defined by the scope of the claim attached hereto. In addition, although several preferred embodiments are disclosed in the present disclosure, they are not intended to limit this disclosure.

Terms such as “features”, “benefits”, and the like introduced throughout the specification are not all features and benefits that can be achieved by using the present disclosure and should/could not be achieved in any single embodiment of the present disclosure. In contrast, the terms relating to features and benefits are understood to mean that the particular features, benefits, or characteristics described in conjunction with the embodiments are included in at least one embodiment of the present disclosure. Thus, the discussion of the terms “features”, “benefits”, and the like throughout the specification may, but does not necessarily, represent the same embodiment.

Furthermore, the features, benefits, and characteristics described in the present disclosure may be combined in any suitable manner in one or more embodiments. According to the description herein, those having ordinary knowledge in the art to which the present disclosure belongs will realize that the present disclosure can be implemented without one or more of particular features or benefits of a particular embodiment. In other instances, additional features and benefits may be shown in some embodiments while they may not be shown in all embodiments of the present disclosure.

What is claimed is:

1. A quantum dot structure, comprising:
a quantum dot comprising:
a core;
a first shell discontinuously around a core surface of the core; and
a second shell between the core and the first shell and encapsulating the core surface, wherein the second shell has an irregular outer surface; and
a cloud-like shell covering a portion of the quantum dot and having an irregular outer surface.

2. The quantum dot structure as claimed in claim 1, wherein a projection of the quantum dot onto a plane has a maximum width in a first direction and a maximum length in a second direction perpendicular to the first direction, a projection of the cloud-like shell onto the plane overlaps with the projection of the quantum dot onto the plane in an overlapping region, and an area of the overlapping region conforms to the following formula:
maximum width*maximum length≥area of the overlapping region≥¼*maximum width*maximum length,
wherein an extending direction of a maximum diameter of the quantum dot is defined as the first direction, the direction perpendicular to the first direction is defined as the second direction, and the plane is defined by the first direction and the second direction.

3. The quantum dot structure as claimed in claim 1, further comprising a first gap between the cloud-like shell and the first shell and a second gap between the cloud-like shell and the second shell.

4. The quantum dot structure as claimed in claim 1, wherein the cloud-like shell, the first shell, and the second shell comprise the same materials.

5. The quantum dot structure as claimed in claim 1, wherein the irregular outer surface of the cloud-like shell has a different surface profile than that of the second shell.

6. The quantum dot structure as claimed in claim 1, wherein the irregular outer surface of the second shell is a concave-convex outer surface comprising a lowest point and a highest point, and a height difference between the lowest point and the highest point of the concave-convex outer surface is greater than 0 nm and less than or equal to 5 nm.

7. The quantum dot structure as claimed in claim 1, wherein the irregular outer surface of the second shell has one recessed portion, and a recessed width of the recessed portion is greater than 0 nm and less than or equal to 10 nm.

8. The quantum dot structure as claimed in claim 1, wherein the first shell comprises a plurality of particles.

9. The quantum dot structure as claimed in claim 8, wherein some of the particles are stacked on top of each other.

10. The quantum dot structure as claimed in claim 1, further comprising ligands above the surfaces of the first shell, the second shell and/or the cloud-like shell.

11. A method of forming quantum dot structures, comprising:
providing a quantum dot core solution comprising a plurality of cores;
providing a shell precursor solution to the quantum dot core solution to form a quantum dot precursor solution;
heating the quantum dot precursor solution at a first temperature to form a quantum dot solution comprising a plurality of quantum dots, wherein each of the quantum dots comprises a first shell and a second shell above a core surface of a core, wherein the first shell is discontinuously formed around the core surface, the second shell is formed between the core and the first shell and encapsulating the core surface, and the second shell has an irregular outer surface; and
continuously stirring the quantum dot solution at a second temperature to form quantum dot structures, wherein each of the quantum dot structures has a cloud-like shell covering a portion of the quantum dot and wherein the second temperature is greater than or equal to the first temperature.

12. The method of forming quantum dot structures as claimed in claim 11, wherein the shell precursor solution is introduced into the quantum dot core solution at an introduction rate, and the introduction rate of the shell precursor solution is 0.016-1.6 eq/min when the core content in the quantum dot core solution is counted as 1 equivalent.

13. The method of forming quantum dot structures as claimed in claim 11, wherein the cloud-like shell has an irregular outer surface.

14. The method of forming quantum dot structures as claimed in claim 11, wherein the second temperature is greater than or equal to 250° C. and less than or equal to 310° C.

15. The method of forming quantum dot structures as claimed in claim 11, wherein the step of providing the shell precursor solution to the quantum dot core solution comprises:
introducing a first shell precursor solution at a first introduction rate, and
introducing a second shell precursor solution at a second introduction rate,
wherein the first introduction rate is 0.016-1.6 eq/min and the second introduction rate is 0.016-1.6 eq/min when the core content in the quantum dot core solution is counted as 1 equivalent, and
wherein the first introduction rate is greater than or equal to the second introduction rate.

16. The method of forming quantum dot structures as claimed in claim 11, further comprising performing a purification process after forming the quantum dot structures.

17. A light-emitting device, comprising:
a light source emitting a first light; and
a wavelength conversion component absorbing part of the first light and converting the part of the first light into a second light, wherein the wavelength conversion component comprises a quantum dot stricture as claimed in claim 1.
